(19) United States
(12) Patent Application Publication
(10) Pub. No.: US 2023/0207541 A1
(43) Pub. Date: Jun. 29, 2023

(54) SEMICONDUCTOR DEVICE

(71) Applicant: FLOSFIA INC., Kyoto (JP)

(72) Inventors: Hideaki YANAGIDA, Kyoto (JP); Takashi SHINOHE, Kyoto (JP); Hiroyuki ANDO, Kyoto (JP); Yusuke MATSUBARA, Kyoto (JP); Hidehito KITAKADO, Kyoto (JP)

(21) Appl. No.: 18/111,227

(22) Filed: Feb. 17, 2023

Related U.S. Application Data
(63) Continuation-in-part of application No. PCT/JP2021/030688, filed on Aug. 20, 2021.

(30) Foreign Application Priority Data
Aug. 20, 2020 (JP) 2020-139470

(51) Int. Cl. H01L 25/16; H01L 23/00; H01L 23/538; H02P 27/06; H02P 29/024

(52) U.S. Cl. CPC H01L 25/16; H01L 24/20; H01L 23/5383; H01L 23/5386; H01L 23/5389; H02P 27/06; H02P 29/027; H01L 2924/10253; H01L 2924/1067; H01L 2924/12031; H01L 2924/12032; H01L 2924/12036; H01L 2924/1207; H01L 2924/13091

(57) ABSTRACT

Provided is a semiconductor device including, a plurality of PN junction diodes each having a negative temperature characteristic and connected to each other in series; a plurality of resistance elements connected respectively to the PN junction diodes in parallel and connected to each other in series; and a Schottky barrier diode having a positive temperature characteristic and connected to the PN junction diodes in parallel.

### CROSS REFERENCE TO RELATED APPLICATION

This application is a continuation-in-part application of International Patent Application No. PCT/JP2021/030688 (Filed on Aug. 20, 2021), which claims the benefit of priority from Japanese Patent Application No. 2020-139470 (filed on Aug. 20, 2020).

The entire contents of the above applications, which the present application is based on, are incorporated herein by reference.

### 1. FIELD OF THE INVENTION

The disclosure relates to a semiconductor device, more specifically, to a semiconductor device that achieves improvement in durability against an overcurrent.

### 2. DESCRIPTION OF THE RELATED ART

Semiconductor devices have been applied to products of every field in recent years and accordingly, have become capable of fulfilling complicated functions of target products by using a plurality of semiconductor elements. Many of these semiconductor devices have a switching function for converting electric power supplied from an external power source and supplying a certain current or voltage to a target product. Furthermore, a structure against an overcurrent is provided in a semiconductor element or in a circuit to allow protection of the target product from an overcurrent.

In an exemplary known semiconductor device, three series-connected PN junction diodes are connected to a Schottky barrier diode in parallel. Setting a total of forward voltages of the three series-connected PN junction diodes greater than a forward voltage of one Schottky barrier diode causes a forward current to flow in the Schottky barrier diode in a normal operation period. On the occurrence of an overcurrent such as a surge current, the forward voltage of the Schottky barrier diode becomes greater to allow electrical conduction through the PN junction diode. As a result, the Schottky barrier diode is protected from the overcurrent.

### SUMMARY OF THE INVENTION

According to an example of the present disclosure, there is provided a semiconductor device including, a plurality of PN junction diodes each having a negative temperature characteristic and connected to each other in series; a plurality of resistance elements connected respectively to the PN junction diodes in parallel and connected to each other in series; and a Schottky barrier diode having a positive temperature characteristic and connected to the PN junction diodes in parallel.

According to an example of the present disclosure, there is provided a semiconductor device including, a plurality of PN junction diodes each having a partial pressure resistor and a negative temperature characteristic and connected to each other in series; and a Schottky barrier diode having a positive temperature characteristic and connected to the PN junction diodes in parallel.

According to an example of the present disclosure, there is provided a semiconductor device including, a PN junction diode having a negative temperature characteristic; a resistance element connected to the PN junction diode in parallel; and a MOSFET (metal-oxide-semiconductor field effect transistor) having a positive temperature characteristic and connected to the PN junction diode in parallel.

According to an example of the present disclosure, there is provided a semiconductor device including, a PN junction diode having a partial pressure resistor and a negative temperature characteristic; and a MOSFET (metal-oxide-semiconductor field effect transistor) having a positive temperature characteristic and connected to the PN junction diode in parallel.

Thus, in a semiconductor device of the present disclosure, a semiconductor device that achieves maintenance of durability against an overcurrent is provided.

### BRIEF DESCRIPTION OF THE DRAWINGS

FIG. 1 is a sectional view showing an internal layout of a semiconductor device according to a first embodiment of the disclosure.

FIG. 2 is a schematic plan view showing the internal layout of the semiconductor device according to the first embodiment of the disclosure.

FIG. 3 is a schematic circuit configuration diagram showing the semiconductor device according to the disclosure.

FIG. 4 is a graph showing an I-V curve for explaining the operation of the semiconductor device of the disclosure.

FIG. 5 is a sectional view showing an internal layout of a semiconductor device according to a second embodiment of the disclosure.

FIG. 6 is a schematic plan view showing the internal layout of the semiconductor device according to the second embodiment of the disclosure.

FIG. 7 is a schematic circuit configuration diagram showing a semiconductor device according to a third embodiment of the disclosure.

FIG. 8 is a block configuration diagram showing an example of a control system employing the semiconductor device according to the embodiment of the disclosure.

FIG. 9 is a circuit diagram showing an example of the control system employing the semiconductor device according to the embodiment of the disclosure.

FIG. 10 is a block configuration diagram showing a different example of the control system employing the semiconductor device according to the embodiment of the disclosure.

FIG. 11 is a circuit diagram showing the different example of the control system employing the semiconductor device according to the embodiment of the disclosure.

### DETAILED DESCRIPTION

As a result of an individual difference in leakage current (reverse current) between the PN junction diodes, a voltage originally to be distributed uniformly may become nonuniform at any of the PN junction diodes. By an influence caused by such non-uniformity, a large voltage acts on a particular one of the PN junction diodes. Hence, this PN junction diode undergoes an overload to be degraded rapidly in performance or damaged in some cases. The performance of the series-connected PN junction diodes is also lost in a short time, causing a risk of failing to fulfill a function of protecting the Schottky barrier diode sufficiently.

In a semiconductor device of the present disclosure, by the presence of the resistors (partial pressure resistors) connected to respectively to the PN junction diodes in parallel, it is possible to distribute a voltage to be applied properly to each of the PN junction diodes. Thus, in particular, in response to application of a reverse voltage to the series-connected PN junction diodes, it is possible to reduce the occurrence of a situation where an excessive voltage is applied to a particular one of the PN junction diodes and this PN junction diode undergoes an overload. As a result, the semiconductor device that achieves improvement in durability against an overcurrent while encouraging size reduction and higher density is provided.

Embodiments of the present disclosure will be described below with reference to the accompanying drawings. In the following description, the same parts and components are designated by the same reference numerals. The present embodiment includes, for example, the following disclosures.

[Structure 1]

A semiconductor device including: a plurality of PN junction diodes each having a negative temperature characteristic and connected to each other in series; a plurality of resistance elements connected respectively to the PN junction diodes in parallel and connected to each other in series; and a Schottky barrier diode having a positive temperature characteristic and connected to the PN junction diodes in parallel.

[Structure 2]

The semiconductor device according to [Structure 1], wherein a total of respective forward voltages of the PN junction diodes is greater than a forward voltage of the Schottky barrier diode.

[Structure 3]

The semiconductor device according to [Structure 1] or [Structure 2], wherein the PN junction diodes are vertical diodes.

[Structure 4]

The semiconductor device according to [Structure 1] or [Structure 2], wherein the PN junction diodes are horizontal diodes.

[Structure 5]

The semiconductor device according to any one of [Structure 1] to [Structure 4], wherein each of the PN junction diodes contains silicon.

[Structure 6]

The semiconductor device according to any one of [Structure 1] to [Structure 5], wherein the PN junction diodes include a PiN diode.

[Structure 7]

The semiconductor device according to any one of [Structure 1] to [Structure 6], wherein the Schottky barrier diode contains gallium oxide or mixed crystal of gallium oxide.

[Structure 8]

A semiconductor device including: a plurality of PN junction diodes each having a partial pressure resistor and a negative temperature characteristic and connected to each other in series; and a Schottky barrier diode having a positive temperature characteristic and connected to the PN junction diodes in parallel.

[Structure 9]

The semiconductor device according to [Structure 8], wherein a total of respective forward voltages of the PN junction diodes is greater than a forward voltage of the Schottky barrier diode.

[Structure 10]

The semiconductor device according to [Structure 8] or [Structure 9], wherein the PN junction diodes are vertical diodes.

[Structure 11]

The semiconductor device according to [Structure 8] or [Structure 9], wherein the PN junction diodes are horizontal diodes.

[Structure 12]

The semiconductor device according to any one of [Structure 8] to [Structure 11], wherein each of the PN junction diodes contains silicon.

[Structure 13]

The semiconductor device according to any one of [Structure 8] to [Structure 12], wherein the PN junction diodes include a PiN diode.

[Structure 14]

The semiconductor device according to any one of [Structure 8] to [Structure 13], wherein the Schottky barrier diode contains gallium oxide or mixed crystal of gallium oxide.

[Structure 15]

A semiconductor device including: a PN junction diode having a negative temperature characteristic; a resistance element connected to the PN junction diode in parallel; and a MOSFET (metal-oxide-semiconductor field effect transistor) having a positive temperature characteristic and connected to the PN junction diode in parallel.

[Structure 16]

A semiconductor device including: a PN junction diode having a partial pressure resistor and a negative temperature characteristic; and a MOSFET (metal-oxide-semiconductor field effect transistor) having a positive temperature characteristic and connected to the PN junction diode in parallel.

[Structure 17]

A power converter using the semiconductor device according to any one of [Structure 1] to [Structure 16].

[Structure 18]

A control system using the semiconductor device according to any one of [Structure 1] to [Structure 16].

Semiconductor devices according to embodiments of the disclosure will be described below by referring to the drawings.

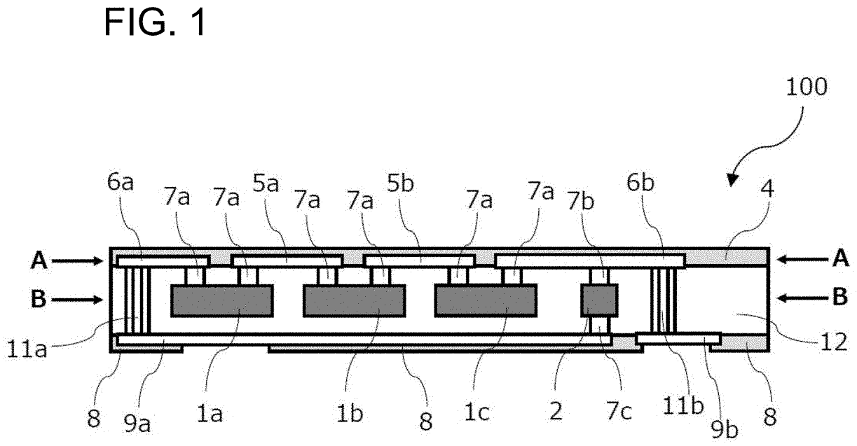

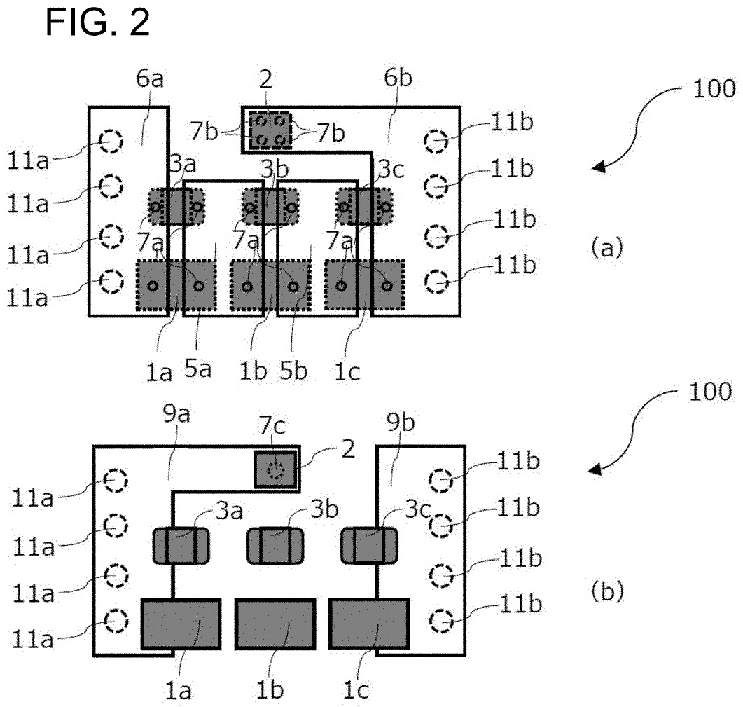

FIG. 1 is a sectional view showing an internal layout of a semiconductor device according to a first embodiment of the disclosure. FIG. 2(a) is a schematic plan view of the semiconductor device taken from a plane including a line A-A in FIG. 1. FIG. 2(b) is a schematic plan view of the semiconductor device taken from a plane including a line B-B in FIG. 1.

A semiconductor device 100 according to the present embodiment includes electronic components including three horizontal PN junction diodes 1a, 1b, and 1c each composed of a semiconductor element, one Schottky barrier diode 2, and three resistors (partial pressure resistors) 3a, 3b, and 3c shown in FIGS. 2(a) and 2(b). These PN junction diodes 1a, 1b, and 1c, Schottky barrier diode 2, and resistors 3a, 3b, and 3c are covered or impregnated with a reinforced plastic layer 12 and integrated with each other. Of these components, the PN junction diodes 1a, 1b, and 1c, and the resistors 3a, 3b, and 3c have upper surfaces where electrical connections are intended to be made respectively through a plurality of vias 7a formed between these components and a die pad 5a, a die pad 5b, a terminal 6a, and a terminal 6b laid at the lower surface of a first substrate 4 shown in FIG. 1. The Schottky barrier diode 2 has an upper surface and a lower surface where electrical connections are intended through a via 7b formed between the Schottky barrier diode 2 and the terminal 6b and through a via 7c formed between the Schottky barrier diode 2 and a terminal 9a respectively.

Meanwhile, a plurality of through holes 11a with the terminals 6a and 9a at both ends and a plurality of through holes 11b with the terminal 6b and a terminal 9b at both ends are formed between the first substrate 4 and a second substrate 8. Electrical connection between the terminal 6a and the terminal 9a is formed through the through holes 11a. Electrical connection between the terminal 6b and the terminal 9b is formed through the through holes 11b. The semiconductor device 100 is electrically connected through these through holes 11a and 11b and using an interconnect line to a different semiconductor device in a control system not shown in the drawing mentioned herein, for example. The first substrate 4 and the second substrate 8 each have an external surface coated with an insulating film for protecting a circuit pattern that may be a solder resist not shown in the drawings, for example, thereby ensuring the insulating property of the semiconductor device 100.

To facilitate understanding of the description, the Schottky barrier diode 2 in FIG. 1 is drawn toward the right from its mounting position in FIG. 2 and near the through hole 11b.

The following describes an electrically connected state of the electronic components forming the semiconductor device 100 according to the first embodiment of the disclosure. As shown in FIG. 2(a), the three horizontal PN junction diodes 1a, 1b, and 1c are electrically connected to each other in series through the vias 7a in a layout as follows from left to right in the drawing: terminal 6a, PN junction diode 1a, die pad 5a, PN junction diode 1b, die pad 5b, PN junction diode 1c, and terminal 6b. The resistors 3a, 3b, and 3c are electrically connected to each other in series through the vias 7a in a layout as follows from left to right in the drawing: terminal 6a, resistor 3a, die pad 5a, resistor 3b, die pad 5b, resistor 3c, and terminal 6b. In terms of connection to the die pads 5a and 5b and the terminals 6a and 6b, electrical and parallel connection is formed respectively between the PN junction diode 1a and the resistor 3a, between the PN junction diode 1b and the resistor 3b, and between the PN junction diode 1c and the resistor 3c.

As shown in FIGS. 2(a) and 2(b), the upper surface of the Schottky barrier diode 2 is electrically connected to the terminal 6b through the vias 7b, and the lower surface of the Schottky barrier diode 2 is electrically connected to the terminal 9a through the vias 7c. The terminal 6a and the terminal 9a are electrically connected to each other through the through holes 11a, and the terminal 6b and the terminal 9b are electrically connected to each other through the through holes 11b. As clearly understood therefrom, the three series-connected PN junction diodes 1a, 1b, and 1c, and the Schottky barrier diode 2 are both connected to the terminals 6a and 6b. As a result, the Schottky barrier diode 2 and the three series-connected PN junction diodes 1a, 1b, and 1c are electrically connected to each other in parallel.

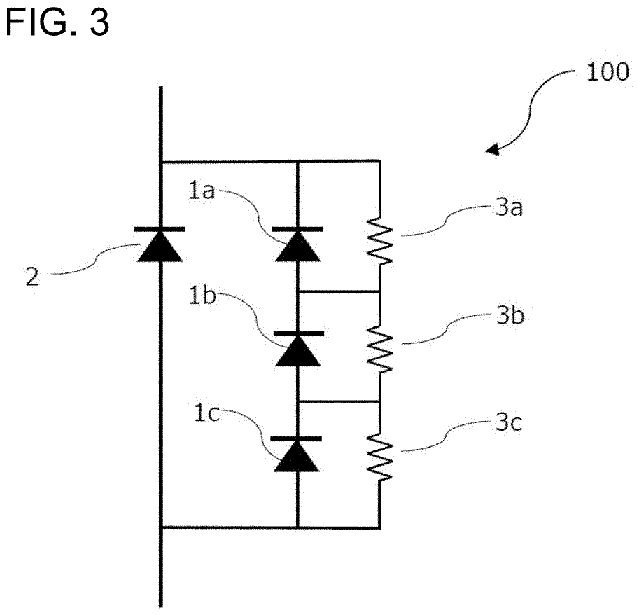

FIG. 3 shows a schematic circuit configuration of the semiconductor device 100 shown in FIGS. 1 and 2. This configuration includes a plurality of the series-connected PN junction diodes 1a, 1b, and 1c, a plurality of the resistors 3a, 3b, and 3c connected respectively to these PN junction diodes 1a, 1b, and 1c in parallel and connected to each other in series, and the Schottky barrier diode 2 connected to the PN junction diodes 1a, 1b, and 1c in parallel. By understanding the circuit configuration shown in FIG. 3 as a Schottky barrier diode having an overcurrent protection function, it becomes possible to apply the semiconductor device 100 of the present embodiment to an existing product using a Schottky barrier diode such as an inverter, a converter, or a rectifier.

The PN junction diode used in the present embodiment has a negative temperature characteristic at least under an overcurrent condition. In this case, a PN junction diode containing Si is preferred, for example. A PiN diode with an i layer interposed between a P layer and an N layer involved in a PN junction is also usable. This makes it possible to encourage improvement in a breakdown voltage.

Meanwhile, the Schottky barrier diode used in the present embodiment has a positive temperature characteristic at least under an overcurrent condition. In this case, a Schottky barrier diode containing gallium oxide (Ga₂O₃) is preferred, for example. In particular, in terms of a switching characteristic of a Schottky barrier diode, using corundum gallium oxide (α-Ga₂O₃) is preferred. A Schottky barrier diode containing mixed crystal including gallium oxide is also preferred. A Schottky barrier diode containing mixed crystal with aluminum (Al) or indium (In) is particularly preferred.

A forward voltage of each of the PN junction diodes 1a, 1b, and 1c is lower than a forward voltage of the Schottky barrier diode 2. Meanwhile, a forward voltage determined in a case of connecting the PN junction diodes 1a, 1b, and 1c to each other in series, specifically, a total of the respective forward voltages of the PN junction diodes 1a, 1b, and 1c is set greater than the forward voltage of the Schottky barrier diode 2. For example, the PN junction diodes 1a, 1b, and 1c to be used each have a forward voltage of 0.7 V and the Schottky barrier diode 2 to be used has a forward voltage of 1.5 V.

The semiconductor device 100 is used as a power semiconductor module or a semiconductor unit to be mounted on various types of power devices, for example.

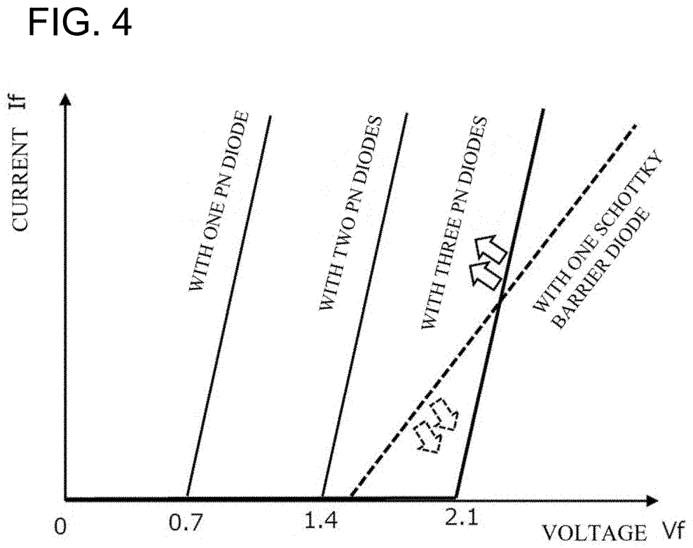

The operation of the semiconductor device 100 according to the first embodiment of the disclosure having the above-described configuration will be described by referring to an I-V characteristic graph in FIG. 4.

If one PN junction diode having a forward voltage of 0.7 V and one Schottky barrier diode having a forward voltage of 1.5 V are connected to each other in parallel, a current flows in the PN junction diode at a forward bias voltage of 0.7 V and a current does not flow in the Schottky barrier diode to operate at a voltage of equal to or greater than 1.5 V. Likewise, if two PN junction diodes each having a forward voltage of 0.7 V are connected to each other in series and are connected in parallel to one Schottky barrier diode having a forward voltage of 1.5 V, a current also flows in the PN junction diodes at a voltage of 1.4 V and the Schottky barrier diode is not caused to operate.

By contrast, if three PN junction diodes each having a forward voltage of 0.7 V are connected to each other in series and are connected in parallel to one Schottky barrier diode having a forward voltage of 1.5 V, a current flows in the Schottky barrier diode at a voltage of 1.5 V so a current does not flow in the three series-connected PN junction diodes having a forward voltage of 2.1 V as a whole. Specifically, by connecting PN junction diodes of an arbitrary number to each other in series in such a manner as to provide a value greater than a forward voltage value of one Schottky barrier diode, it becomes possible to provide electrical conduction through the series-connected PN junction diodes only on the occurrence of an overcurrent and to cause only the Schottky barrier diode to operate in a normal operation period.

In the semiconductor device 100 according to the first embodiment, a total of respective forward voltages of the PN junction diodes 1a, 1b, and 1c (0.7 V+0.7 V+0.7 V=2.1 V) is greater than a forward voltage of the Schottky barrier diode 2 (1.5 V). This causes a current to flow only in the Schottky barrier diode 2 in the normal operation period to form electrical conduction across the terminals 6a and 9a and across the terminals 6b and 9b.

On the other hand, on the occurrence of flow of an overcurrent such as a surge current, a high voltage (a voltage significantly beyond 2.1 V) is generated momentarily. In this case, this overcurrent is allowed to be conducted through the three PN junction diodes 1a, 1b, and 1c connected to the Schottky barrier diode 2 in parallel. Specifically, by making design in such a manner as to conduct a forward current through the three series-connected PN junction diodes 1a, 1b, and 1c only on the occurrence of an overcurrent, it becomes possible to prevent damage on the Schottky barrier diode 2 due to the overcurrent.

By connecting the resistors 3a, 3b, and 3c respectively to the PN junction diodes 1a, 1b, and 1c in parallel, it becomes possible to apply a uniform voltage to each of the PN junction diodes 1a, 1b, and 1c particularly during application of a reverse voltage. This allows reduction in the occurrence of concentration of load on a particular one of the PN junction diodes, thereby providing the semiconductor device that achieves improvement in durability against an overcurrent while encouraging size reduction and higher density.

Furthermore, in the present embodiment, the Schottky barrier diode 2 has a positive temperature characteristic. Thus, a forward voltage becomes larger as a temperature becomes higher to make it more difficult to cause a current to flow. This indicates that a line with dashes shown in FIG. 4 gradually slopes to be approximated to a horizontal direction (gradually lies down). On the other hand, the PN junction diodes 1a, 1b, and 1c each have a negative temperature characteristic. Thus, a forward voltage becomes smaller as a temperature becomes higher to cause a current to flow more easily. This indicates that lines expressed as solid lines in FIG. 4 gradually slope to be approximated to a vertical direction (gradually rises up). This provides the series-connected PN junction diodes 1a, 1b, and 1c with a forward voltage lower than a total of respective forward voltages of the PN junction diodes 1a, 1b, and 1c at the time of design, making it possible to conduct a generated overcurrent reliably. In particular, in the first embodiment, the PN junction diodes 1a, 1b, and 1c, and the Schottky barrier diode 2 are integrated with each other by being provided inside the reinforced plastic layer 12. This allows heat generated from the Schottky barrier diode 2 to be transferred easily to the PN junction diodes 1a, 1b, and 1c to achieve effective use of the negative temperature characteristic of each of the PN junction diodes 1a, 1b, and 1c.

Preferably, a total of respective reverse breakdown voltages of the series-connected PN junction diodes 1a, 1b, and 1c is set about equal to or greater than a reverse breakdown voltage of the Schottky barrier diode 2. If the reverse breakdown voltage of the Schottky barrier diode 2 is 600 V, for example, the PN junction diodes 1a, 1b, and 1c to be used each have a reverse breakdown voltage of equal to or greater than 200 V.

According to the semiconductor device 100 of the present embodiment to operate in the above-described manner, the semiconductor device that achieves improvement in durability against an overcurrent while encouraging size reduction and higher density is provided.

If the semiconductor device is applied to a power device, it is preferable to use a semiconductor element having an excellent bandgap characteristic. In the present embodiment, the Schottky barrier diode 2 may be formed using a material including silicon carbide (SiC) or gallium nitride (GaN). Meanwhile, using oxide semiconductor containing gallium oxide (Ga₂O₃) having a wider bandgap characteristic for forming the Schottky barrier diode 2 provides the semiconductor device with higher performance and compactness.

While an operating temperature of the PN junction diode is properly settable in in response to a purpose of application, etc., the PN junction diode is preferably configured to operate at a temperature of equal to or less than 175° C., for example.

Other embodiments of the disclosure will be described below. In the following description, a constituting element common to the first embodiment will be given the same sign and explanation thereof overlapping between the embodiments will be omitted.

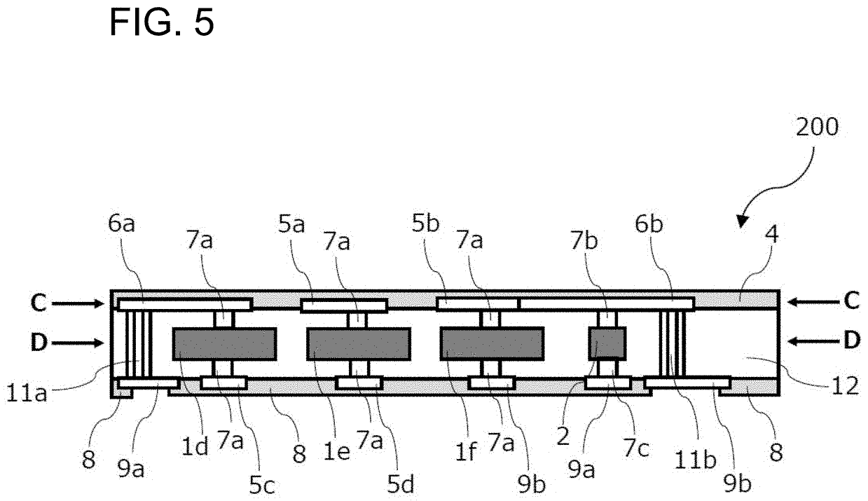

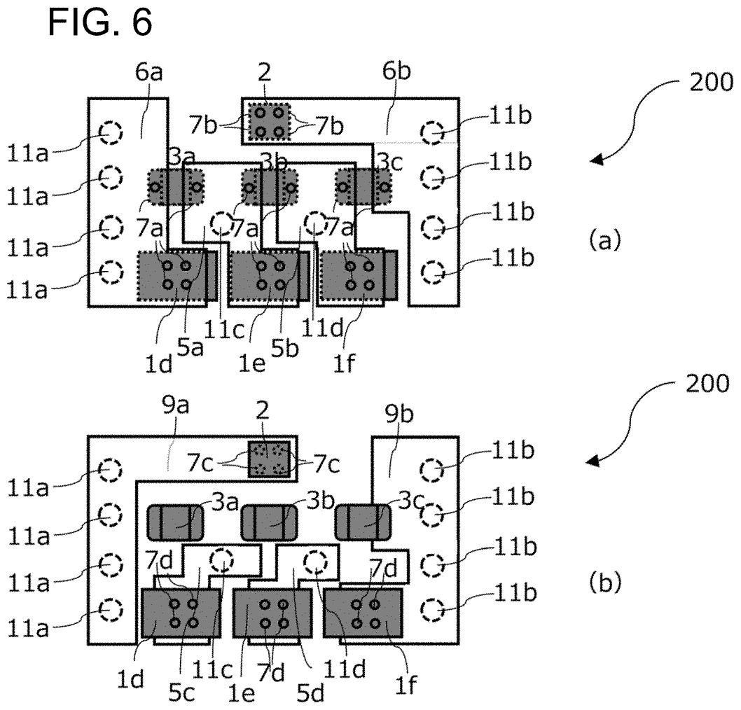

FIG. 5 is a sectional view showing an internal layout of a semiconductor device according to a second embodiment of the disclosure. FIG. 6(a) is a schematic plan view of the semiconductor device taken from a plane including a line C-C in FIG. 5. FIG. 6(b) is a schematic plan view of the semiconductor device taken from a plane including a line D-D in FIG. 5.

A semiconductor device 200 shown in this drawing is equipped with a PN junction diode 1d, a PN junction diode 1e, and a PN junction diode 1f differing from those of the semiconductor device 100 in FIG. 1. Specifically, all these PN junction diodes 1d, 1e, and 1f are vertical PN junction diodes and each have an upper surface and a lower surface provided with electrical contacts. Electrical connections are formed through a plurality of vias 7d to a die pad 5c and a die pad 5d newly provided and to the terminal 9b that are formed at the upper surface of the second substrate 8 and at positions facing the lower surfaces of the PN junction diodes 1d, 1e, and 1f respectively. By doing so, the PN junction diode 1d is electrically connected to the terminal 6a and the die pad 5c, the PN junction diode 1e is electrically connected to the die pad 5a and the die pad 5d, and the PN junction diode 1f is electrically connected to the die pad 5b and the terminal 9b. Furthermore, a through holes 11c with the die pad 5a and the die pad 5c at both ends and a through hole 11d with the die pads 5b and 5d at both ends are formed between the first substrate 4 and the second substrate 8. Electrical connection between the die pad 5a and the die pad 5c and electrical connection between the die pad 5b and the die pad 5d are formed through the through holes 11c and 11d respectively.

To facilitate understanding of the description of the present embodiment, the Schottky barrier diode 2 in FIG. 5 is also drawn toward the right from its mounting position in FIG. 6 and near the through hole 11b.

In the semiconductor device 200 having the above-described configuration, a circuit configuration comparable to that of the first embodiment shown in FIG. 3 is formed, thereby achieving effect comparable to that achieved by the first embodiment. Furthermore, using the vertical PN junction diodes is also expected to achieve effects such as a higher breakdown voltage, a higher current, and a lower ON resistance.

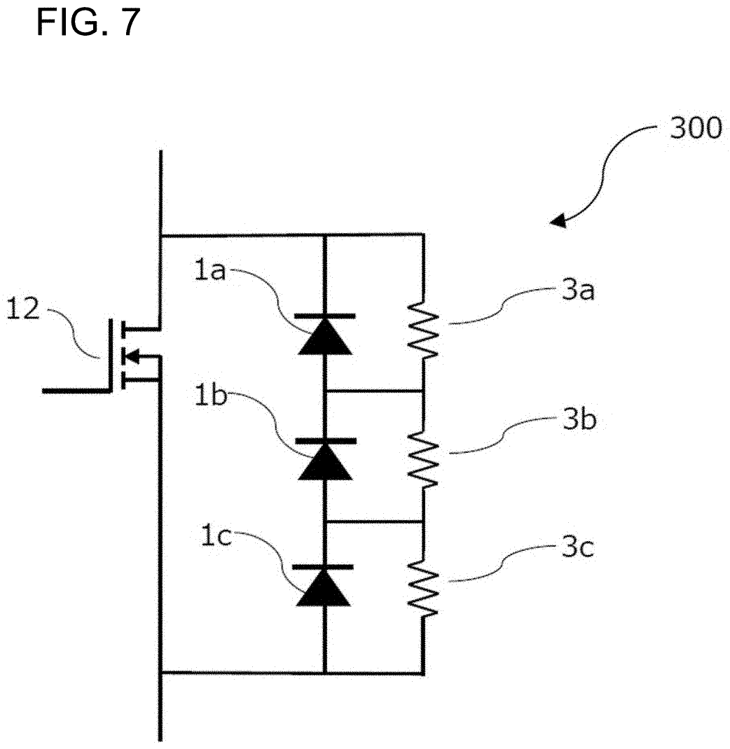

FIG. 7 is a schematic circuit configuration diagram showing a semiconductor device according to a third embodiment of the disclosure. Like the schematic circuit configuration of the semiconductor device 100 shown in FIG. 3, a semiconductor device 300 of the present embodiment has a schematic circuit configuration including one or more series-connected PN junction diodes 1a, 1b, and 1c, and a plurality of the resistors 3a, 3b, and 3c connected respectively to these PN junction diodes 1a, 1b, and 1c in parallel and connected to each other in series. The semiconductor device 300 of the present embodiment further includes a MOSFET (metal-oxide-semiconductor field effect transistor) 12 for synchronous rectification instead of the Schottky barrier diode 2 in FIG. 3. In the present embodiment, PN junction diodes of an arbitrary number (one, or two or more) are connected to each other in series, for example, in such a manner that a total value of respective partial pressures (forward voltage values) of these PN junction diodes is greater than a forward voltage value of one MOSFET. By doing so, it becomes possible to provide electrical conduction through the PN junction diode only on the occurrence of an overcurrent and to cause only the MOSFET to operate in a normal operation period. For this reason, if a forward voltage value of one PN junction diode is greater than a forward voltage value of one MOSFET 12, the number of the PN junction diodes may be one. Specifically, in the present embodiment, the number of the PN junction diodes is not limited to that in the configuration shown in FIG. 7. Like in the above-described embodiments, such a circuit configuration realizes the semiconductor device 300 encouraging improvement in durability of the MOSFET for synchronous rectification against an overcurrent. Like the Schottky barrier diode 2, the MOSFET 12 for synchronous rectification may certainly be formed using a material including silicon carbide (SiC) or gallium nitride (GaN), and may also be formed using oxide semiconductor containing gallium oxide (Ga₂O₃) having a wider bandgap characteristic. By doing so, the semiconductor device is provided with higher performance and compactness.

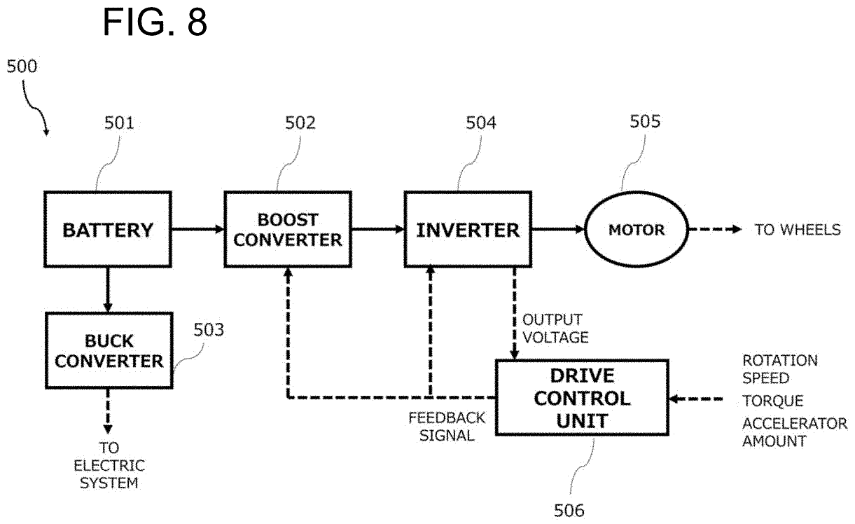

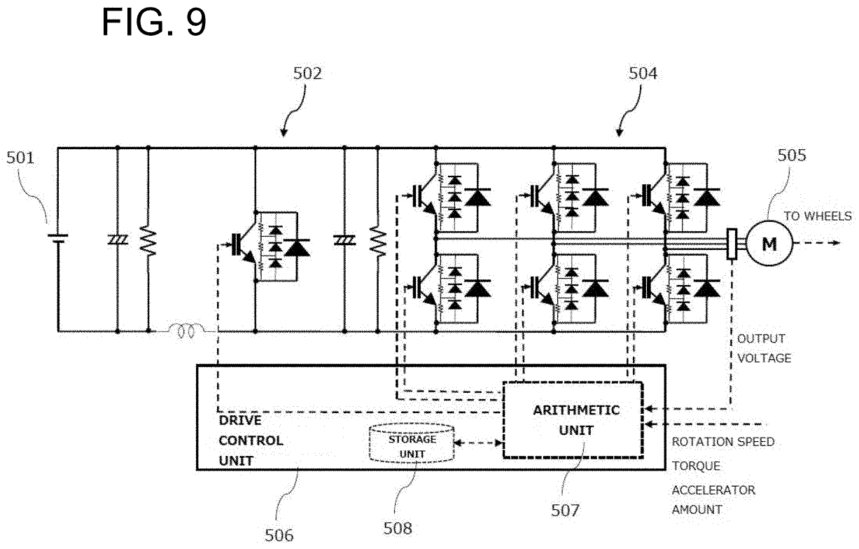

To cause the semiconductor device of the disclosure described above to fulfill the foregoing function, this semiconductor device may be applied to a power converter such as an inverter or a converter. More preferably, the semiconductor device may be applied as a diode provided in an inverter or a converter and may be used in combination with a switching element that may be a thyristor, a power transistor, an IGBT (insulated gate bipolar transistor), or the MOSFET for synchronous rectification illustrated in FIG. 7, for example. FIG. 8 is a block configuration diagram showing an example of a control system using the semiconductor device according to the embodiment of the disclosure. FIG. 9 is a circuit diagram of this control system, which is a circuit diagram of a control system to be mounted particularly suitably on an electric vehicle.

As shown in FIG. 8, the control system 500 includes a battery (power supply) 501, a boost converter 502, a buck converter 503, an inverter 504, a motor (driving object) 505, a drive control unit 506, which are mounted on an electric vehicle. The battery 501 consists of, for example, a storage battery such as a nickel hydrogen battery or a lithium-ion battery. The battery 501 can store electric power by charging at the power supply station or regenerating at the time of deceleration, and to output a direct current (DC) voltage required for the operation of the driving system and the electrical system of the electric vehicle. The boost converter 502 is, for example, a voltage converter in which a chopper circuit is mounted, and can step-up DC voltage of, for example, 200 V supplied from the battery 501 to, for example, 650 V by switching operations of the chopper circuit. The step-up voltage can be supplied to a traveling system such as a motor. The buck converter 503 is also a voltage converter in which a chopper circuit is mounted, and can step-down DC voltage of, for example, 200 V supplied from the battery 501 to, for example, about 12 V. The step-down voltage can be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505. The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506. The output voltage value of the inverter 504 is also input to the drive control unit 506 at the same time. The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements. The AC voltage supplied to the motor 505 from the inverter 504 is thus corrected instantaneously, and the driving control of the electric vehicle can be executed accurately. Safety and comfortable operation of the electric vehicle is thereby realized. In addition, it is also possible to control the output voltage to the inverter 504 by providing a feedback signal from the drive control unit 506 to the boost converter 502.

FIG. 9 is a circuit configuration excluding the buck converter 503 in FIG. 8, in other words, a circuit configuration showing a configuration only for driving the motor 505. As shown in the FIG. 9, the semiconductor device of the disclosure is provided for switching control by, for example, being applied to the boost controller 502 and the inverter 504 as a Schottky barrier diode. The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504. The current can be stabilized by interposing an inductor (such as a coil) at the output of the battery 501. Also, the voltage can be stabilized by interposing a capacitor (such as an electrolytic capacitor) between each of the battery 501, the boost converter 502, and the inverter 504.

As indicated by a dotted line in FIG. 9, an arithmetic unit 507 including a CPU (Central Processing Unit) and a storage unit 508 including a nonvolatile memory are provided in the drive control unit 506. Signal input to the drive control unit 506 is given to the arithmetic unit 507, and a feedback signal for each semiconductor element is generated by performing the programmed operation as necessary. The storage unit 508 temporarily holds the calculation result by the calculation unit 507, stores physical constants and functions necessary for driving control in the form of a table, and outputs the physical constants, functions, and the like to the arithmetic unit 507 as appropriate. The arithmetic unit 507 and the storage unit 508 can be provided by a known configuration, and the processing capability and the like thereof can be arbitrarily selected.

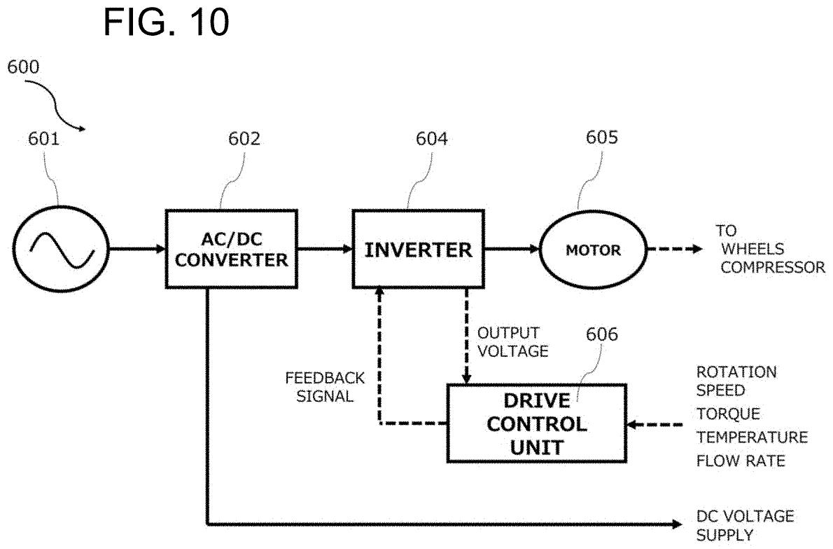

As shown in FIGS. 9 and 10, a diode and a switching element such as a thyristor, a power transistor, an IGBT, a MOSFET and the like is employed for the switching operation of the boost converter 502, the buck converter 503 and the inverter 504 in the control system 500. The use of gallium oxide (Ga 2 O3) specifically corundum-type gallium oxide (α-Ga 2 O3) as its materials for these semiconductor devices greatly improves switching properties. Further, extremely outstanding switching performance can be expected and miniaturization and cost reduction of the control system 500 can be realized by applying a semiconductor film or a semiconductor device of the disclosure. That is, each of the boost converter 502, the buck converter 503 and the inverter 504 can be expected to have the benefit of the disclosure, and the effect and the advantages can be expected in any one or combination of the boost converter 502, the buck converter 503 and the inverter 504, or in any one of the boost converter 502, the buck converter 503 and the inverter 504 together with the drive control unit 506. The control system 500 described above is not only applicable to the control system of an electric vehicle of the semiconductor device of the disclosure, but can be applied to a control system for any applications such as to step-up and step-down the power from a DC power source, or convert the power from a DC to an AC. It is also possible to use a power source such as a solar cell as a battery.

FIG. 10 is a block diagram illustrating another exemplary control system applying a semiconductor device according to an embodiment of the disclosure, and FIG. 13 is a circuit diagram of the control system suitable for applying to infrastructure equipment and home appliances or the like operable by the power from the AC power source.

As shown in FIG. 10, the control system 600 is provided for inputting power supplied from an external, such as a three-phase AC power source (power supply) 601, and includes an AC/DC converter 602, an inverter 604, a motor (driving object) 605 and a drive control unit 606 that can be applied to various devices described later. The three-phase AC power supply 601 is, for example, a power plant (such as a thermal, hydraulic, geothermal, or nuclear plant) of an electric power company, whose output is supplied as an AC voltage while being downgraded through substations. Further, the three-phase AC power supply 601 is installed in a building or a neighboring facility in the form of a private power generator or the like for supplying the generated power via a power cable. The AC/DC converter 602 is a voltage converter for converting AC voltage to DC voltage. The AC/DC converter 602 converts AC voltage of 100 V or 200 V supplied from the three-phase AC power supply 601 to a predetermined DC voltage. Specifically, AC voltage is converted by a transformer to a desired, commonly used voltage such as 3.3 V, 5 V, or 12 V. When the driving object is a motor, conversion to 12 V is performed. It is possible to adopt a single-phase AC power supply in place of the three-phase AC power supply. In this case, same system configuration can be realized if an AC/DC converter of the single-phase input is employed.

The inverter 604 converts the DC voltage supplied from the AC/DC converter 602 into three-phase AC voltage by switching operations and outputs to the motor 605. Configuration of the motor 605 is variable depending on the control object. It can be a wheel if the control object is a train, can be a pump and various power source if the control objects a factory equipment, can be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC inverter 602. In that case the inverter 604 becomes unnecessary in the control system 600, and a DC voltage from the AC/DC inverter 602 is supplied to the driving object directly as shown in FIG. 10. Here, DC voltage of 3.3 V is supplied to personal computers and DC voltage of 5 V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606. At the same time, the output voltage value of the inverter 604 is also input to the drive control unit 606.

Based on these measured signals, the drive control unit 606 provides a feedback signal to the inverter 604 thereby controls switching operations by the switching element of the inverter 604. The AC voltage supplied to the motor 605 from the inverter 604 is thus corrected instantaneously, and the operation control of the driving object can be executed accurately. Stable operation of the driving object is thereby realized. In addition, when the driving object can be driven by a DC voltage, as described above, feedback control of the AC/DC controller 602 is possible in place of feedback control of the inverter.

FIG. 13 shows the circuit configuration of FIG. 10. As shown in FIG. 13, the semiconductor device of the disclosure is provided for switching control by, for example, being applied to the AC/DC converter 602 and the inverter 604 as a Schottky barrier diode. The AC/DC converter 602 has, for example, a circuit configuration in which Schottky barrier diodes are arranged in a bridge-shaped, to perform a direct-current conversion by converting and rectifying the negative component of the input voltage to a positive voltage. Schottky barrier diodes can also be applied to a switching circuit in IGBT of the inverter 604 to perform switching control. The voltage can be stabilized by interposing a capacitor (such as an electrolytic capacitor) between the AC/DC converter 602 and the inverter 604.

As indicated by a dotted line in FIG. 13, an arithmetic unit 607 including a CPU and a storage unit 608 including a nonvolatile memory are provided in the drive control unit 606. Signal input to the drive control unit 606 is given to the arithmetic unit 607, and a feedback signal for each semiconductor element is generated by performing the programmed operation as necessary. The storage unit 608 temporarily holds the calculation result by the arithmetic unit 607, stores physical constants and functions necessary for driving control in the form of a table, and outputs the physical constants, functions, and the like to the arithmetic unit 607 as appropriate. The arithmetic unit 607 and the storage unit 608 can be provided by a known configuration, and the processing capability and the like thereof can be arbitrarily selected.

In such a control system 600, similarly to the control system 500 shown in FIGS. 8 and 9, a diode or a switching element such as a thyristor, a power transistor, an IGBT, a MOSFET or the like is also applied for the purpose of the rectification operation and switching operation of the AC/DC converter 602 and the inverter 604.

Switching performance can be improved by the use of gallium oxide (Ga₂O₃), particularly corundum-type gallium oxide (α-Ga₂O₃), as materials for these semiconductor elements. Further, extremely outstanding switching performance can be expected and miniaturization and cost reduction of the control system 600 can be realized by applying a semiconductor film or a semiconductor device of the disclosure. That is, each of the AC/DC converter 602 and the inverter 604 can be expected to have the benefit of the disclosure, and the effects and the advantages of the disclosure can be expected in any one or combination of the AC/DC converter 602 and the inverter 604, or in any of the AC/DC converter 602 and the inverter 604 together with the drive control unit 606.

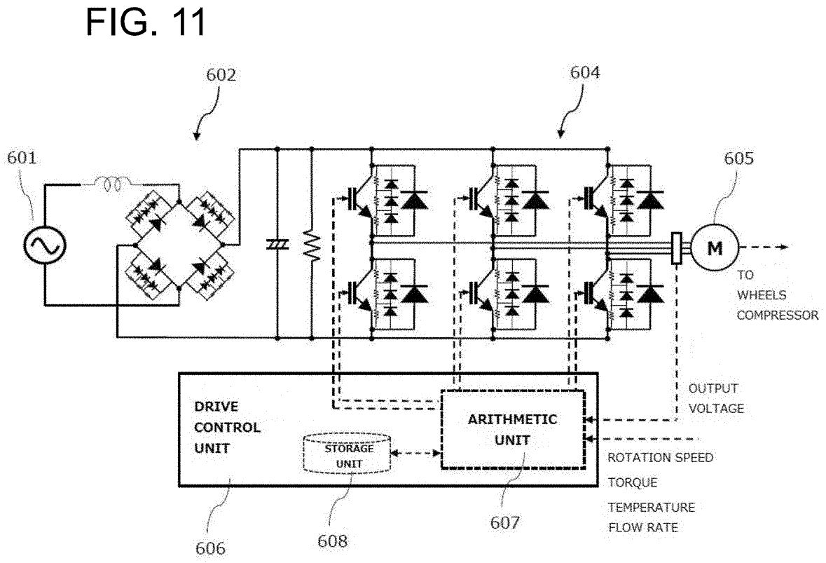

Although the motor 605 has been exemplified in FIGS. 10 and 11, the driving object is not necessarily limited to those that operate mechanically. Many devices that require an AC voltage can be a driving object. It is possible to apply the control system 600 as long as electric power is obtained from AC power source to drive the driving object. The control system 600 can be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

While each of the embodiments of the disclosure has been described above, the disclosure shall not be limited to these embodiments but the disclosure certainly becomes implementable by being modified in various ways within a range not deviating from the purport of the disclosure.

For example, while the Schottky barrier diode and the PN junction diode are mounted on respective die pads (or terminals) in the first or second embodiment described above, the PN junction diode is mountable on a die pad (or terminal) common to the Schottky barrier diode. In this case, heat generated from the Schottky barrier diode is transferred through the die pads to the PN junction diode, allowing the PN junction diode having a negative temperature characteristic to exhibit its negative temperature characteristic more effectively at the time of an overcurrent.

The number of the series-connected PN junction diodes is not limited to three. By giving consideration to a relationship between a forward voltage of the Schottky barrier diode and a forward voltage of the PN junction diode to be employed (FIG. 4), a surge breakdown voltage, a reverse breakdown voltage, etc., an arbitrary number becomes settable. In this case, while it is also required to set a total of breakdown voltages of a plurality of PN junction diodes greater than a breakdown voltage of the Schottky barrier diode, a smaller difference in breakdown voltage therebetween is preferred. Preferably, the total of the breakdown voltages and the breakdown voltage of the Schottky barrier diode are set substantially equal to each other.

Resistors connected to the PN junction diodes in parallel are not required to have resistance values equal to each other. Specifically, from the viewpoint of the purpose of avoiding imposition of an excessive load on any of a plurality of series-connected PN junction diodes, resistance values are not required to be set completely equal to each other but a range of the resistance values or non-uniformity between the resistance values are permissible as appropriate. If a breakdown voltage characteristic differs between a plurality of PN junction diodes, resistors responsive to these breakdown voltages are connected respectively to the PN junction diodes in parallel. Specifically, by giving consideration to a purpose of use or set lifetime of a semiconductor device, etc., it is possible to select a plurality of PN junction diodes having respective values and a plurality of resistors having respective values to be connected respectively to these PN junction diodes in parallel. This is also expected to achieve the effect of the disclosure.

In FIG. 9 or 11, for example, design is preferably made in such a manner that both a total of breakdown voltages of a plurality of PN junction diodes and a breakdown voltage of a Schottky barrier diode become less than a breakdown voltage of a switching element connected in parallel to the PN junction diodes and the Schottky barrier diode.

In the exemplary case of the above-described embodiments, the disclosure is mounted on a so-called substrate-embedded module package. However, the disclosure shall not be limited to such a package shape. For example, the disclosure is implementable in a configuration of mounting on various types of IC packages belonging to surface mounting, insertion mounting, or contact mounting. In response to a purpose of application, design is made arbitrarily in terms of the size of a package, the number of terminals or the widths of the terminals to be mounted on the package, etc.

It is certainly possible to combine two or more embodiments according to the disclosure or apply some constituting elements to other embodiments. Such configurations also belong to the embodiments of the disclosure.

The embodiments of the present invention are exemplified in all respects, and the scope of the present invention includes all modifications within the meaning and scope equivalent to the scope of claims.

### REFERENCE SIGNS LIST

1a, 1b, 1c, 1d, 1e, 1f PN junction diode
2 Schottky barrier diode
3a, 3b, 3c Resistor (partial pressure resistor)
4 First substrate
5a, 5b, 5c, 5d Die pad
6a, 6b, 9a, 9b Terminal
7a, 7b, 7c, 7d Via
8 Second substrate
11a, 11b, 11c, 11d Through hole
12 MOSFET
100, 200, 300 Semiconductor device
500 control system
501 battery (power supply)
502 boost converter
503 buck converter
504 inverter
505 motor (driving object)
506 drive control unit
507 arithmetic unit
508 storage unit
600 control system
601 three-phase AC power supply
602 AC/DC converter
604 inverter
605 motor (driving object)
606 drive control unit
607 arithmetic unit
608 storage unit

What is claimed is:

1. A semiconductor device comprising:
a plurality of PN junction diodes each having a negative temperature characteristic and connected to each other in series;
a plurality of resistance elements connected respectively to the PN junction diodes in parallel and connected to each other in series; and
a Schottky barrier diode having a positive temperature characteristic and connected to the PN junction diodes in parallel.

2. The semiconductor device according to claim 1, wherein
a total of respective forward voltages of the PN junction diodes is greater than a forward voltage of the Schottky barrier diode.

3. The semiconductor device according to claim 1, wherein
the PN junction diodes are vertical diodes.

4. The semiconductor device according to claim 1, wherein
the PN junction diodes are horizontal diodes.

5. The semiconductor device according to claim 1, wherein
each of the PN junction diodes contains silicon.

6. The semiconductor device according to claim 1, wherein
the PN junction diodes include a PiN diode.

7. The semiconductor device according to claim 1, wherein
the Schottky barrier diode contains gallium oxide or mixed crystal of gallium oxide.

8. A semiconductor device comprising:
a plurality of PN junction diodes each having a partial pressure resistor and a negative temperature characteristic and connected to each other in series; and
a Schottky barrier diode having a positive temperature characteristic and connected to the PN junction diodes in parallel.

9. The semiconductor device according to claim 8, wherein
a total of respective forward voltages of the PN junction diodes is greater than a forward voltage of the Schottky barrier diode.

10. The semiconductor device according to claim 8, wherein
the PN junction diodes are vertical diodes.

11. The semiconductor device according to claim 8, wherein
the PN junction diodes are horizontal diodes.

12. The semiconductor device according to claim 8, wherein
each of the PN junction diodes contains silicon.

13. The semiconductor device according to claim 8, wherein
the PN junction diodes include a PiN diode.

14. The semiconductor device according to claim 8, wherein
the Schottky barrier diode contains gallium oxide or mixed crystal of gallium oxide.

15. A semiconductor device comprising:
a PN junction diode having a negative temperature characteristic;
a resistance element connected to the PN junction diode in parallel; and
a MOSFET (metal-oxide-semiconductor field effect transistor) having a positive temperature characteristic and connected to the PN junction diode in parallel.

16. A semiconductor device comprising:
a PN junction diode having a partial pressure resistor and a negative temperature characteristic; and
a MOSFET (metal-oxide-semiconductor field effect transistor) having a positive temperature characteristic and connected to the PN junction diode in parallel.

17. A power converter using the semiconductor device according to claim 1.

18. A control system using the semiconductor device according to claim 1.
